(19) United States
(12) Patent Application Publication
(10) Pub. No.: US 2006/0018491 A1
(43) Pub. Date: Jan. 26, 2006

(54) Single-sided Bessel array

(76) Inventor: Enrique M. Stiles, Imperial Beach, CA (US)

Correspondence Address: RICHARD C. CALDERWOOD, 2775 NW 126TH AVE, PORTLAND, OR, 97229-8381, US

(21) Appl. No.: 10/896,215

(22) Filed: Jul. 20, 2004

(51) Int. Cl. H04R 1/40; H03G 5/00

(52) U.S. Cl. 381/97; 381/98; 381/117

(57) ABSTRACT

An improved Bessel array of electromagnetic transducers, in which the Bessel coefficients (phase and/or magnitude) are applied only in a high frequency range, where off-axis interference patterns between the outputs of respective transducers cause undesirable acoustic results. One improvement is in using an all-pass filter or the like in lieu of an inverter in the inverting Bessel coefficient path, to provide an in-phase signal in low frequencies and an opposite-phase signal in high frequencies. This achieves the improved off-axis result of a conventional Bessel array, with improved low-frequency maximum sound pressure and efficiency. Another improvement is in using a frequency-dependent voltage divider in the half-strength Bessel coefficient paths, to provide full-strength signals in low frequencies and half-strength signals in high frequencies. This achieves even more improved low-frequency maximum sound pressure.

### BACKGROUND OF THE INVENTION

1. Technical Field of the Invention

This invention relates generally to transducers such as audio speakers, and more specifically to an array of transducers which operate as a Bessel array in higher frequencies and as a conventional array in lower frequencies.

2. Background Art

It is well known to organize two or more transducers together into a variety of array configurations. One popular configuration is the line array.

FIG. 1 illustrates a conventional line array system 10. A plurality of transducers 12 are arranged in a linear fashion. In some instances, the transducers may be substantially identical. Although five transducers are shown, line arrays may use any number of transducers. Commonly, the transducers are coupled to a single, common enclosure 14. The transducers are driven in phase by a common signal (as indicated by the “+1” indication at the input to each transducer) from an amplifier 16.

As compared to a single transducer, a line array composed of multiple units of that same transducer offers the advantage of increased maximum sound pressure (sometimes referred to as loudness or volume), due simply to there being more transducers moving air, and also offers the advantage of higher efficiency, due to mutual air coupling between the transducers leading to improved impedance matching. However, line arrays can suffer from undesirable effects, such as interference patterns, which are observed at off-axis listening positions. In this context, “off-axis” refers to positions which are removed in a direction parallel to the “line” of the line array; for example, in FIG. 1 the off-axis positions are up and down, rather than left and right of the line array. These effects result, in large measure, from the listener being at slightly different distances from each of the respective transducers, and sound from the closer transducers arriving sooner than sound from the farther transducers. The farther off-axis the listener moves, the greater the differences between the listener and each of the transducers. At various off-axis positions, some frequencies will be subject to constructive interference while other frequencies will be subject to destructive interference. At other off-axis positions, different sets of frequencies will be subject to constructive or destructive interference. In general, because high frequencies have shorter wavelengths than low frequencies, these off-axis effects are more pronounced in the higher frequencies and begin to significantly occur when the frequency is sufficiently high such that its wavelength is only twice as long as the spacing between adjacent transducers in the array. At this frequency, the output of two adjacent transducers will completely cancel each other out at an angle of 90 degrees off-axis, because the output of one will be exactly 180 degrees out of phase with the output of the other.

FIG. 2 is a graph that illustrates the performance of one example of a line array, with five transducers on 4 cm center-to-center spacing. The horizontal (X) axis is frequency, and the vertical (Y) axis is sound pressure. Sixteen response curves are plotted; the on-axis curve is shown as a solid line, and the dotted lines represent fifteen response curves measured at 2 degree increments off-axis. The line array exhibits very good performance, with 98 dB sound pressure and minimal interference effects below about 1 kHz. Above about 1 kHz, however, the line array begins to exhibit significant comb filter interference patterns.

U.S. Pat. No. 4,399,328 to Franssen teaches the known but little-used Bessell array of speakers, which was designed to address exactly this problem. Its principles will be explained with reference to FIGS. 2-4.

FIG. 3 illustrates a Bessel array 20 of transducers 12 coupled to an enclosure 14 and driven by an amplifier 16. Rather than simply being provided directly to each transducer, as in a line array, the audio signal from the amplifier is altered to be suitable for the Bessel array by a circuit 22. The amplifier may be a pre-amplifier, and the final power amplification may be performed between the Bessel circuit and the transducers through the use of multiple power amplifiers.

The advantage offered by a Bessel array is control of constructive and destructive interference patterns in listening positions which are off-axis in the direction of the line array—vertically in the example of FIG. 3. A Bessel array reduces this effect by powering the various speaker drivers with differently conditioned signals, rather than by merely splitting the same signal equally five ways. In the common five-driver Bessel array, the first driver 12-1 receives a half-strength, in-phase signal (referred to as “+½”); the second driver 12-2 receives a full-strength, inverted-phase signal (referred to as “−1”); the third and fourth drivers 12-3 and 12-4 each receives a full-strength, in-phase signal (“+1”); and the fifth driver 12-5 receives a half-strength, in-phase signal (“+½”).

One method of providing the “−1” signal is simply to reverse the connections at the + and − terminals of the second driver. One method of providing the “+½” signals is to connect the first and fifth drivers in series with each other, and that series combination in parallel with each of the other drivers, as taught by Franssen. In other embodiments, the Bessel circuit may be e.g. a digital logic device.

In some embodiments, a single amplifier's output is used to drive all of the transducers in the Bessel array. In other embodiments, each transducer may be driven by its own, dedicated amplifier; in such embodiments, each amplifier's output may be adjusted such that its output corresponds to the required Bessel coefficient for that particular driver. In that case, the amplifier settings themselves function as the Bessel circuit.

A Bessel array sacrifices maximum sound pressure and efficiency versus a line array configuration of the same drivers, to gain improved off-axis sound performance. In low frequencies, a five-driver Bessel array uses five speaker drivers to generate the same sound pressure level that would be generated by two speaker drivers in a conventional line array.

FIG. 4 is a graph illustrating the frequency response of a conventional 5-driver Bessel array with 4 cm center-to-center spacing, in 2 degree increments from 30 degrees below to 30 degrees above center. Comparing FIG. 4 to FIG. 2, it is readily seen that the Bessel array has significantly reduced off-axis interference patterns compared to the conventional line array. However, it is also readily seen that the Bessel array has significantly reduced sound pressure than the conventional line array using the same transducers, the same amplifier (although only being driven at ⅘ths relative output), and the same signal—the conventional line array offers roughly 98 dB on-axis, while the Bessel array offers only 90 dB, an 8 dB reduction in the sound pressure level.

Furthermore, it is also seen that the conventional Bessel array performs the same interference pattern reduction, and loss of sound pressure, across the entire frequency range, whereas the interference pattern is really only a problem in the higher frequencies. At lower frequencies, the wavelengths are sufficiently long to swamp the distance difference between the off-axis listener and the respective speaker drivers.

What is desirable, then, is a Bessel array which performs its interference pattern reduction function more in higher frequencies than in lower frequencies and which has less overall reduction in sound pressure and efficiency than a conventional Bessel array.

### BRIEF DESCRIPTION OF THE DRAWINGS

FIG. 1 shows a line array according to the prior art.

FIG. 2 is a graph showing the frequency response of the 5-driver line array of FIG. 1.

FIG. 3 shows a Bessel array according to the prior art.

FIG. 4 is a graph showing the frequency response of the conventional 5-driver Bessel array of FIG. 3.

FIG. 5 shows an improved Bessel array according to one embodiment of this invention.

FIGS. 6A and 6B are graphs showing the frequency response of the improved Bessel array of FIG. 5.

FIG. 7 shows a Bessel square array according to the prior art.

FIG. 8 shows an improved Bessel square array according to another embodiment of this invention.

FIG. 9 shows another embodiment of an improved Bessel square array with the frequency-dependent Bessel coefficient feature applied in both row and column circuitry.

FIG. 10 shows yet another embodiment of an improved Bessel square array.

FIG. 11 shows another embodiment of a Bessel array with an additional improvement in that both the inverted Bessel coefficient and the half-amplitude Bessel coefficients are provided in a frequency dependent manner.

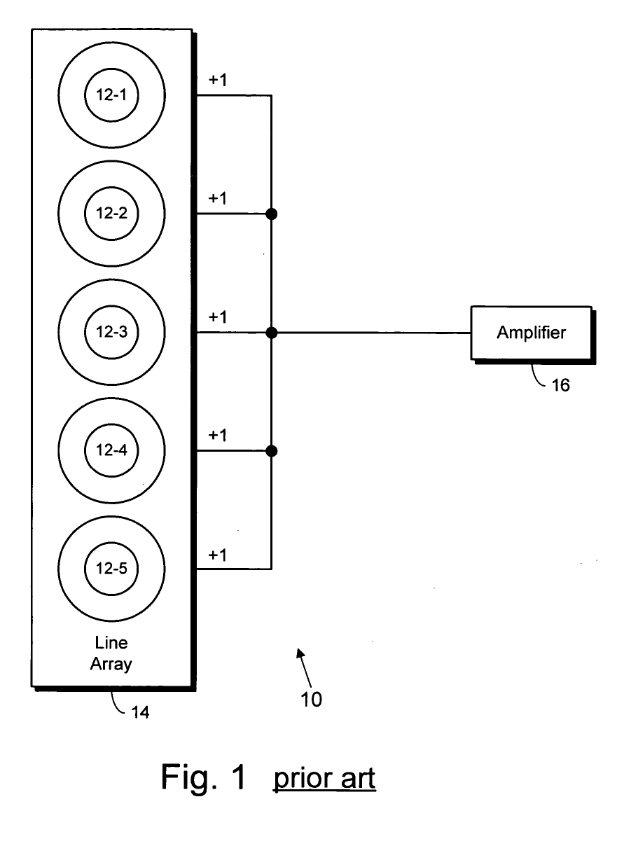

### DETAILED DESCRIPTION

The invention will be understood more fully from the detailed description given below and from the accompanying drawings of embodiments of the invention which, however, should not be taken to limit the invention to the specific embodiments described, but are for explanation and understanding only.

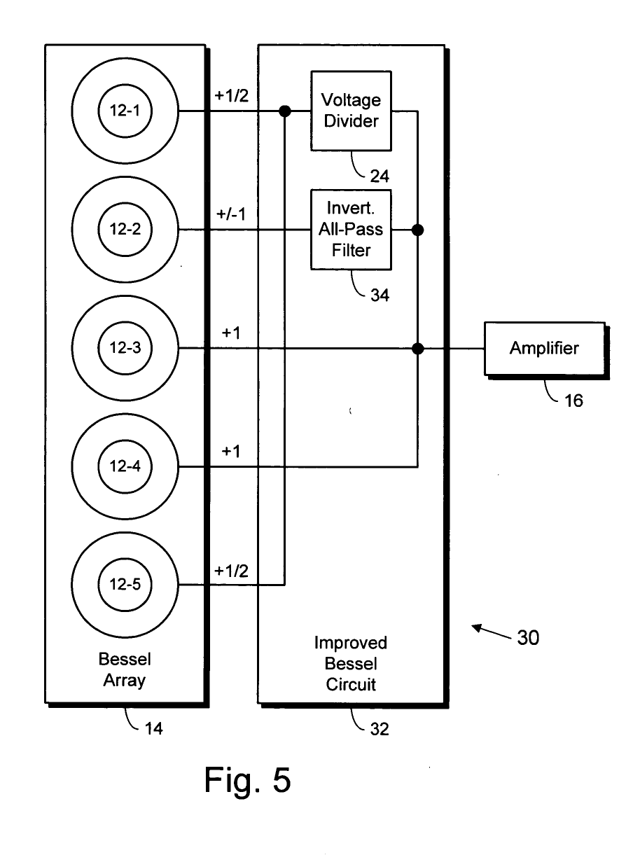

FIG. 5 illustrates one embodiment of an improved Bessel array 30 according to this invention. The Bessel array may use a conventionally configured array of speaker drivers 12-1 to 12-5 mounted in an enclosure 14 and powered by a conventional source such as an amplifier 16.

The improvement lies in the Bessel circuit 32 which conditions the amplifier output to apply the required Bessel coefficients to the signals supplied to each of the respective drivers. In the five-driver Bessel array shown, the first driver 12-1 and fifth driver 12-5 each receives an in-phase, half-strength (“+½”) signal whose strength is reduced by a conventional voltage divider 24 or other suitable means (such as being coupled in series); the second driver 12-2 receives its signal (“+/−1”) from an inverting all-pass filter 34 or other such circuit which performs the desired function; and the third driver 12-3 and fourth driver 12-4 each receives a simple pass-through of the amplifier signal (“+1”).

The inverting all-pass filter inverts the phase of high-frequency signals, but does not invert the phase of low-frequency signals; thus, the signal is identified as “+/−1” suggesting that it is “+1” in lower frequencies and “−1” in higher frequencies. The designer can select the phase-inverting cross-over point to be at any frequency, based on driver spacing and desired off-axis response control.

Thus, the improved Bessel array is a “single-sided” Bessel array, in that it behaves like a Bessel array on one side (the high-frequency side) of its frequency range, but more like a conventional line array on the other side (the low-frequency side). It may also be thought of as being single-sided in that, in some embodiments, it will exhibit better performance in one off-axis direction than in the other.

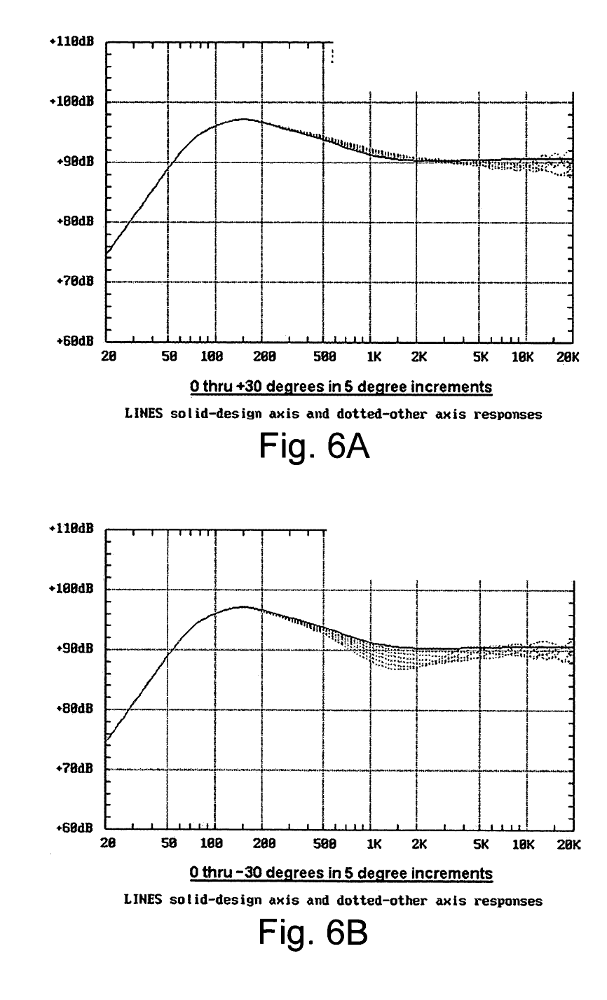

FIGS. 6A and 6B are graphs illustrating the off-axis performance of the improved Bessel array of FIG. 5, which has 5 drivers on 4 cm center-to-center spacing. FIGS. 6A and 6B show the performance from center to 30 degrees above and below center, respectively, in 5 degree increments.

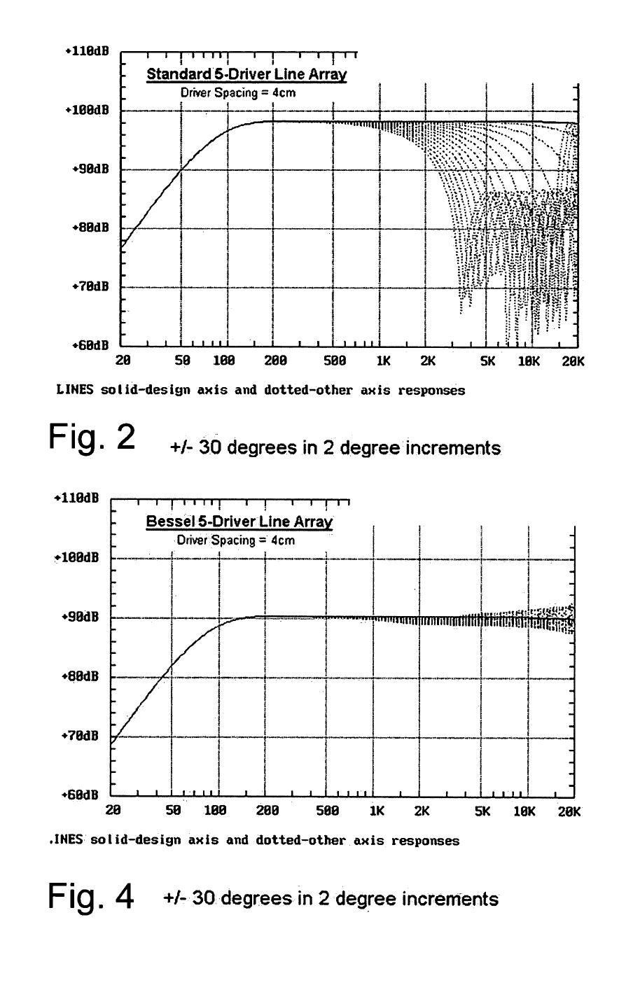

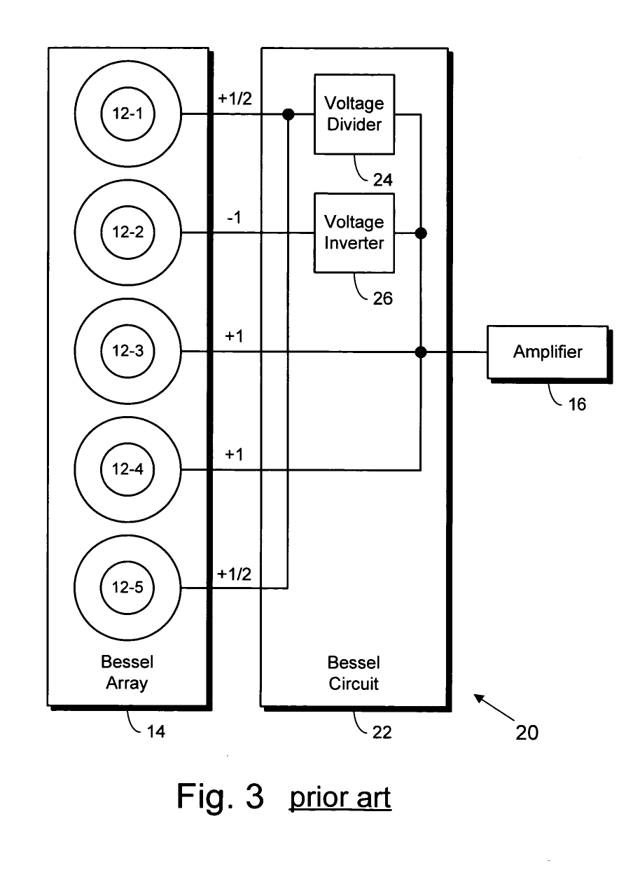

Comparing FIGS. 6, 4, and 2, it is seen that in the lower frequencies, the sound pressure level of the improved Bessel array of this invention is significantly better than that of the conventional Bessel array, and in the higher frequencies, the interference exhibited by the improved Bessel array of this invention is significantly better than that of a conventional line array and nearly as good as the conventional Bessel array. The improved Bessel array is somewhat asymmetrical, as seen by comparing FIG. 6A to FIG. 6B, in that it has a different amount of off-axis interference control in one off-axis direction than in the other.

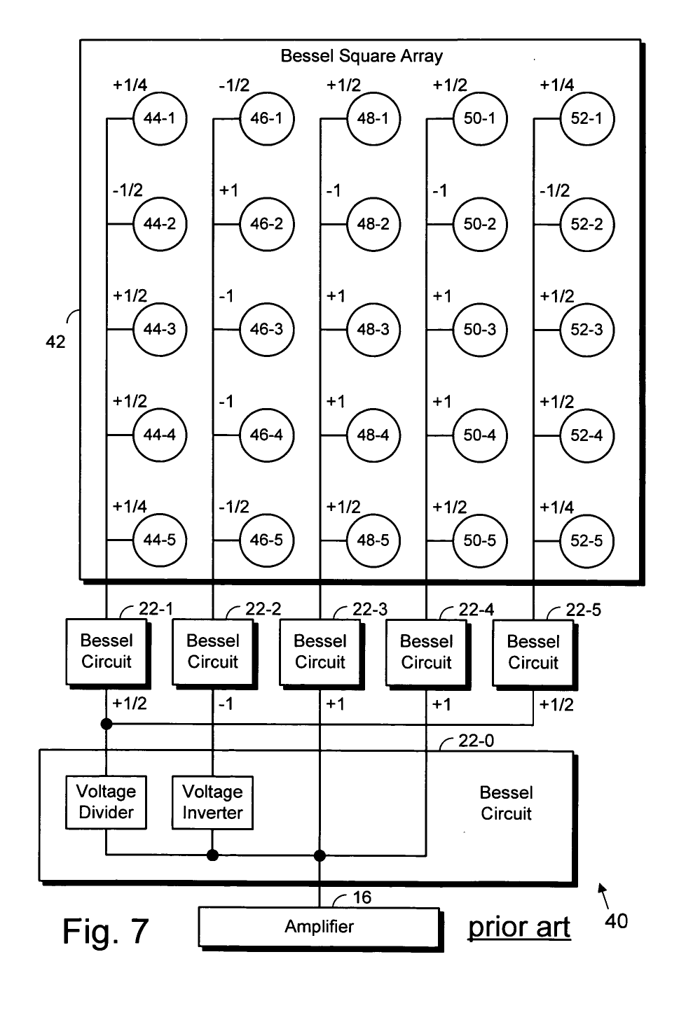

FIG. 7 illustrates a Bessel square array 40 according to the prior art, including an array of speaker drivers coupled to an enclosure 42. The Bessel square array is a “Bessel of Bessels”. The speaker drivers are arranged in a two-dimensional array, typically but not necessarily having equal numbers of rows and columns. The speaker drivers within each given column are driven in Bessel array fashion, and the columns themselves are driven in Bessel array fashion.

The amplifier output is provided to a main Bessel circuit 22-0. Each output of the main Bessel circuit is provided as an input to a respective secondary or column Bessel circuit 22-1 through 22-5. Each of the secondary Bessel circuits drives a corresponding Bessel array of drivers arranged in a column. The first column Bessel circuit 22-1 drives a first Bessel array of drivers 44, the second column Bessel circuit 22-2 drives a second Bessel array of drivers 46, and so forth. Each secondary Bessel circuit applies the Bessel function to whatever input signal it receives from its respective output of the main Bessel circuit. Thus, the signal provided to any given speaker driver is the product of its main and column Bessel signal values.

The five drivers 44 in the first column are driven in Bessel array fashion, with the first driver 44-1 and the fifth driver 44-5 each receives a quarter-strength, in-phase signal “+¼”; the second driver 44-2 receives a half-strength, opposite-phase signal “−½”; and the third driver 44-3 and the fourth driver 44-4 each receives a half-strength, in-phase signal “+½”. The five drivers 52 in the fifth column are driven the same as those in the first column.

The five drivers 46 in the second column are driven collectively by the “−1” of the main Bessel, which is fed through the second column Bessel circuit 22-2. The first driver 46-1 and the fifth driver 46-5 each receives a half-strength, opposite-phase signal “−½”; the second driver 46-2 receives a full-strength, in-phase signal “+1” (a double negative); and the third driver 46-3 and the fourth driver 46-4 each receives a full-strength, opposite-phase signal “−1”.

The third column Bessel circuit 22-3 receives a “+1” signal from the main Bessel circuit. The first driver 48-1 and the fifth driver 48-5 each receives a half-strength, in-phase signal “+½”; the second driver 48-2 receives a full-strength, opposite-phase signal “−1”; and the third driver 48-3 and the fourth driver 48-4 each receives a full-strength, in-phase signal “+1”. The five drivers 50 in the fourth column are driven the same as those in the third column.

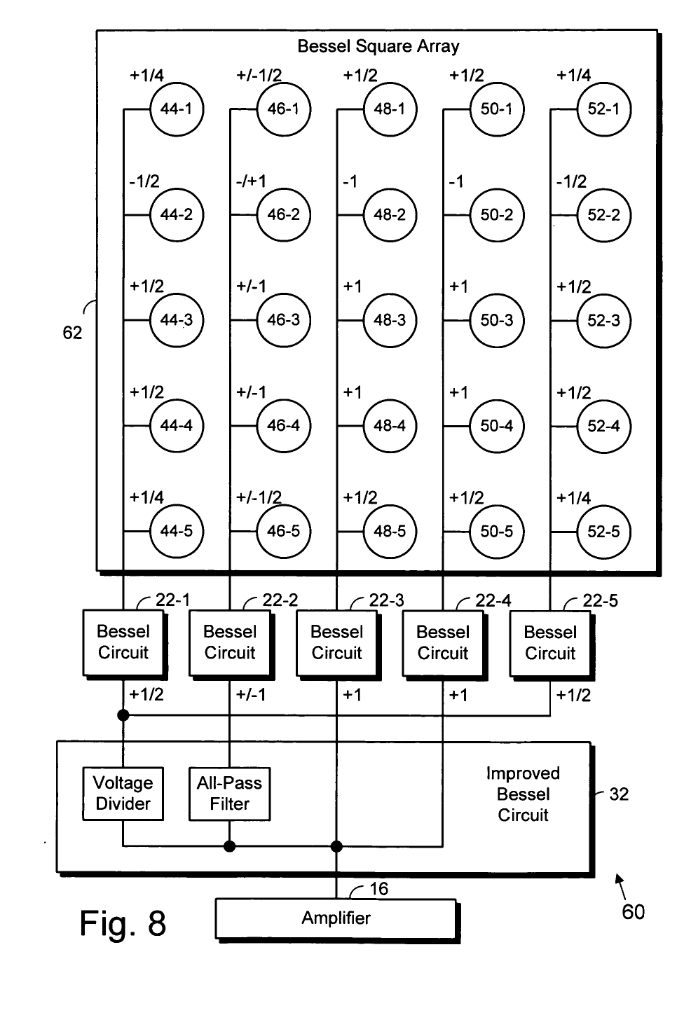

FIG. 8 illustrates the improved Bessel square array 60 according to one embodiment of this invention. In the embodiment shown, the inverting all-pass filter improvement is applied to only the primary Bessel circuit, with the five column Bessel circuits being conventional Bessel circuits which simply invert the phase of their input signals to generate their second drivers' respective signals

The first, third, fourth, and fifth columns' drivers receive the same signals as in the conventional Bessel square array of FIG. 7. The improvement lies in the signals applied to the second column—the position which, in a conventional Bessel array receives the “−1” signal but which, in this invention such as shown in FIG. 5, receives the “+/−1” signal.

The operation of the second column is slightly more complex than in the conventional Bessel square array, because according to this invention it receives a single-sided all-pass filter phase shifted signal “+/−1” from the second output of the primary Bessel circuit.

In the low frequencies, the primary Bessel circuit is outputting a “+1” signal at its second output, and the second column Bessel circuit 22-2 provides a “+½” signal (main “+1” times column “+½”) to the first driver 46-1 and to the fifth driver 46-5; a “−1” (main “+1” times column “−1”) signal to the second driver 46-2; and a “+1” (main “+1” times column “+1”) signal to each of the third driver 46-3 and the fourth driver 46-4.

In the high frequencies, the primary Bessel circuit is outputting a “−1” signal at its second output, and the second column Bessel circuit 22-2 provides a “−½” signal (main “−1” times column “+½”) to the first driver 46-1 and to the fifth driver 46-5; a “+1” (main “−1” times column “−1”) signal to the second driver 46-2; and a “−1” (main “−1” times column “+1”) signal to each of the third driver 46-3 and the fourth driver 46-4.

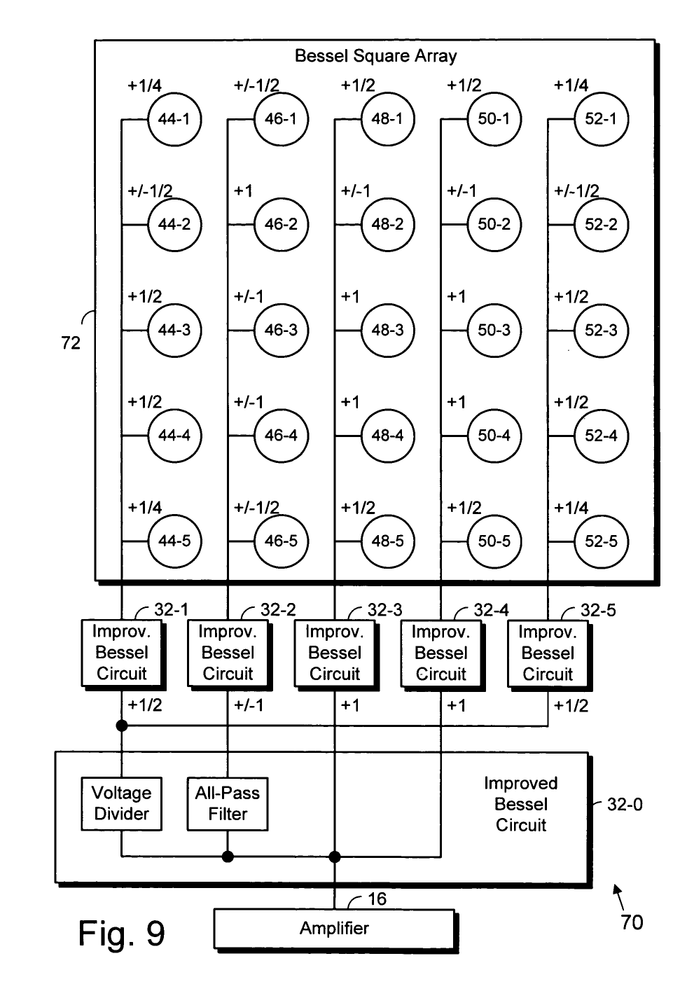

FIG. 9 illustrates another embodiment of an improved Bessel square array 70 in which the improved Bessel circuit is used in both the main (row) Bessel and the column Bessel functions. The output from the amplifier(s) is fed into an improved main Bessel circuit 32-0. The outputs of the main Bessel circuit are fed into respective improved column Bessel circuits 32-1 through 32-5.

The advantage gained over the embodiment of FIG. 8 lies in the second row of transducers. In the low frequencies, each of those five drivers 44-2, 46-2, 48-2, 50-2, and 52-2 receives an in-phase “+” signal, whereas in FIG. 8 each received an opposite phase “−” signal in the low frequencies. In the FIG. 8 configuration, the second row transducers contribute to low frequency sound pressure, rather than diminishing it. The disadvantage is that there are now six instances of the inverting all-pass filter circuitry—one in the main Bessel circuit, and five in the respective column Bessel circuits.

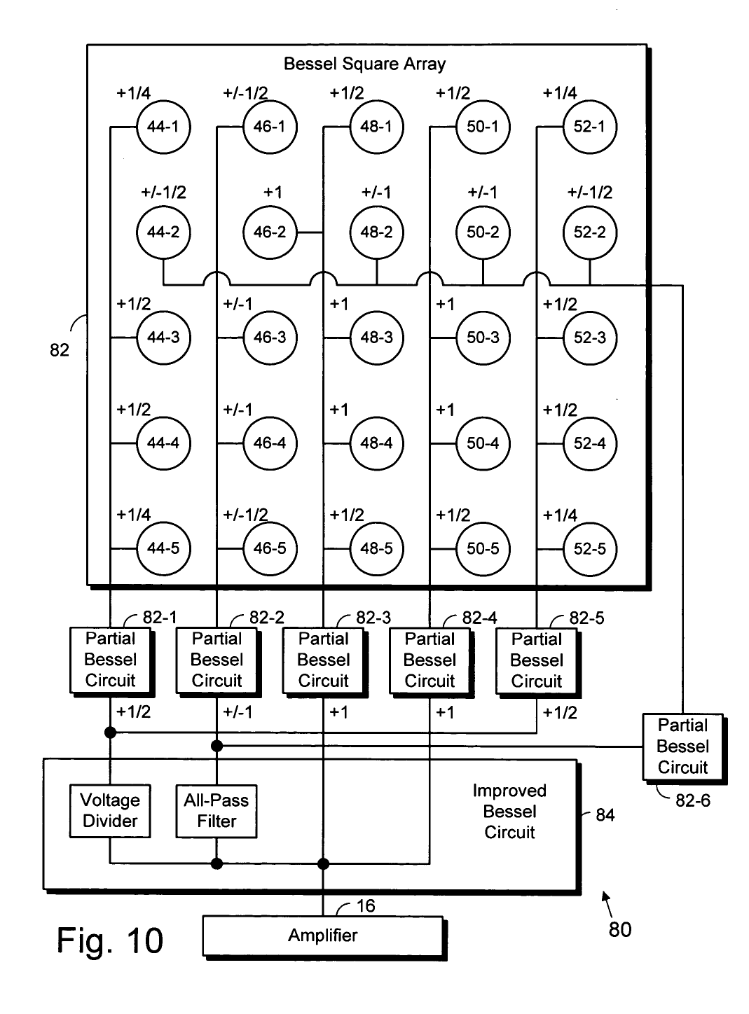

FIG. 10 illustrates another embodiment of a Bessel square array 80 which retains the low frequency performance advantage of FIG. 9, but which requires only a single inverting all-pass filter circuit. The amplifier output is provided to an improved main Bessel circuit 84. The five Bessel coefficient outputs of the main Bessel circuit are fed into five respective column partial Bessel circuits 82-1 through 82-5. These are partial Bessel circuits in that they lack the inverting (second) Bessel output. A sixth partial Bessel circuit 82-6 is driven, in parallel with the second column partial Bessel circuit 82-2, with the frequency-dependent inverting output of the main Bessel circuit. This sixth partial Bessel circuit drives transducers 44-2, 48-2, 50-2, and 52-2 as indicated. The transducer 44-2 which lies at the missing inverting output of both the second column partial Bessel circuit 82-2 and the sixth partial Bessel circuit 82-6 is driven with a “+1” signal, which may be supplied by any handy source such as any other “+1” output or by its own amplifier or what have you.

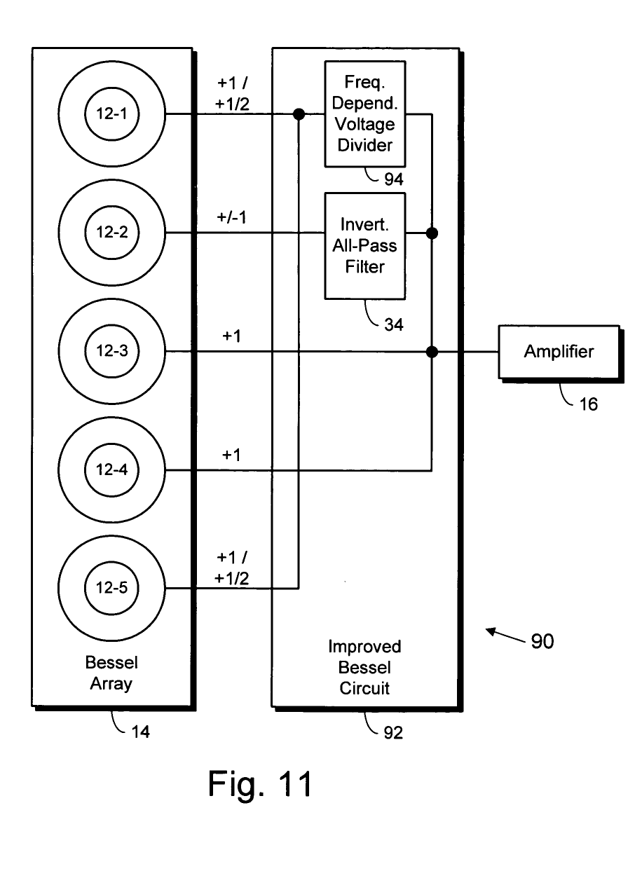

FIG. 11 illustrates the frequency-dependent improvement applied not only to the inverting (second) Bessel signal but also to the half-strength (first and fifth) Bessel signals, as well. The improved Bessel system 90 includes an improved Bessel circuit 92, which includes the inverting all-pass filter 34 providing its second output and the straight pass-through paths providing its third and fourth outputs. In place of a conventional voltage divider (or series connection) at its first and fifth outputs, it includes a frequency-dependent voltage divider 94 providing its first and fifth outputs.

In low frequencies, the frequency-dependent voltage divider does not perform any significant voltage division, and the first and fifth transducers receive full-strength, in-phase “+1” signals; the inverting all-pass filter does not perform phase inversion, and the second transducer receives a full-strength, in-phase “+1” signal; and, as always, the third and fourth transducers receive full-strength, in-phase “+1” signals. Thus, in low frequencies, the improved Bessel array performs substantially like a conventional line array, offering maximum sound pressure and efficiency.

In high frequencies, the frequency-dependent voltage divider performs voltage division, such that the first and fifth transducers receive half-strength, in-phase “+½” signals; the inverting all-pass filter provides a full-strength, opposite-phase “−1” signal to the second transducer; and the third and fourth transducers continue to receive full-strength, in-phase “+1” signals. Thus, in high frequencies, the improved Bessel array performs substantially like a conventional Bessel array, reducing interference patterns in off-axis listening positions.

This frequency-dependent voltage divider improvement can, of course, be applied to a Bessel square array, as well.

### CONCLUSION

The skilled reader will appreciate that the drawings are for illustrative purposes only, and are not scale models of optimized transducer systems.

While the invention has been described with reference to embodiments in which it is configured as an audio speaker, in other embodiments it may be configured as a microphone, or other such apparatus which may be characterized as an electromagnetic transducer.

The term “square” should not be interpreted to limit the invention to e.g. 5×5 Bessel arrays, but should be interpreted to also cover e.g. 5×7 or 9×7 Bessel arrays or what have you.

Transducers need not be coupled to a common enclosure in order to function as a Bessel array. Indeed, low frequency performance will in many cases be improved if various ones of the transducers occupy separate enclosure volume(s) than other transducers. For example, it may generally not be ideal to have two “+1” transducers sharing an enclosure volume with a “−1” transducer, nor even with a “+½” transducer.

When one component is said to be “adjacent” another component, it should not be interpreted to mean that there is absolutely nothing between the two components, only that they are in the order indicated. The various features illustrated in the figures may be combined in many ways, and should not be interpreted as though limited to the specific embodiments in which they were explained and shown. Those skilled in the art having the benefit of this disclosure will appreciate that many other variations from the foregoing description and drawings may be made within the scope of the present invention. Indeed, the invention is not limited to the details described above. Rather, it is the following claims including any amendments thereto that define the scope of the invention.

What is claimed is:

1. An improvement in a Bessel array of electromagnetic transducers coupled to be driven by a Bessel circuit, the Bessel circuit providing a plurality of in-phase output signals and an opposite-phase signal, wherein the improvement comprises:
the opposite-phase signal being provided by an inverting all-pass filter;
whereby an electromagnetic transducer is driven in-phase in a low frequency range and opposite-phase in a high frequency range.

2. The improvement of claim 1 in the Bessel array, wherein the Bessel array includes five electromagnetic transducers in a line array, and wherein the improvement further comprises:
the five electromagnetic transducers being driven, from one end of the line array, with signals comprising,
1) a substantially half-strength, in-phase signal,
2) a substantially full-strength signal which is in-phase in the low frequency range and substantially opposite-phase in the high frequency range,
3) a substantially full-strength, in-phase signal,
4) a substantially full-strength, in-phase signal, and
5) a substantially half-strength, in-phase signal.

3. The improvement of claim 1 in the Bessel array, wherein the Bessel array comprises a Bessel square array, and wherein the improvement further comprises:
the Bessel square array being driven by a main Bessel circuit and a plurality of column Bessel circuits; and
one of the main Bessel circuit and the plurality of column Bessel circuits together having the inverting all-pass filter improvement.

4. The improvement of claim 3 in the Bessel array, wherein the improvement further comprises:
it being the main Bessel circuit which has the all-pass filter improvement.

5. The improvement of claim 3 in the Bessel array, wherein the improvement further comprises:
the plurality of column Bessel circuits being coupled to respective outputs of the main Bessel circuit.

6. The improvement of claim 1 in the Bessel array, wherein the Bessel array comprises a Bessel square array, and wherein the improvement further comprises:
the Bessel square array being driven by a main Bessel circuit and a plurality of column Bessel circuits; and
each of the main Bessel circuit and the plurality of column Bessel circuits together having the inverting all-pass filter improvement.

7. The improvement of claim 1 in the Bessel array, wherein the Bessel array comprises a Bessel square array arranged in columns and rows, wherein there are a plurality of non-inverting columns and an inverting column, and a plurality of non-inverting rows and an inverting row, and wherein the improvement further comprises:
a main Bessel circuit including an inverting output having the inverting all-pass filter and a plurality of non-inverting outputs;
a plurality of column partial Bessel circuits each having an input coupled to a respective output of the main Bessel circuit, and each coupled to drive transducers at non-inverting row positions in a respective column; and
an extra partial Bessel circuit having an input coupled to the inverting output of the main Bessel circuit and coupled to drive transducers at an non-inverting column positions in the inverting row; and
a transducer at the inverting column position and the inverting row position being coupled to be driven by a non-inverting signal.

8. The improvement of claim 1 in the Bessel array wherein the improvement further comprises:
partial-strength signals being provided by a frequency-dependent voltage divider;
whereby transducers are driven at greater strength in a low frequency range than in a high frequency range.

9. A Bessel circuit for driving a Bessel array of electromagnetic transducers with a signal from an amplifier, the Bessel circuit comprising:
at least one half-strength, in-phase circuit path;
a plurality of full-strength, in-phase circuit paths; and
a full-strength circuit path which operates in-phase in low frequencies and opposite-phase in high frequencies.

10. The Bessel circuit of claim 9 wherein:
the full-strength circuit path which operates in-phase in low frequencies and opposite-phase in high frequencies comprises an all-pass filter.

11. The Bessel circuit of claim 9 wherein:
the plurality of full-strength, in-phase circuit paths comprise direct connections from the amplifier to respective electromagnetic transducers; and
each half-strength, in-phase circuit path comprises an in-series connection from the amplifier to two respective electromagnetic transducers.

12. The Bessel circuit of claim 9 wherein:
the plurality of full-strength, in-phase circuit paths comprise direct connections from the amplifier to respective electromagnetic transducers; and
each half-strength, in-phase circuit path comprises a voltage divider.

13. The Bessel circuit of claim 9 wherein:
the half-strength, in-phase circuit paths comprise a frequency-dependent voltage divider.

14. An audio speaker system for coupling to be driven by a signal from an amplifier, the audio speaker system comprising:
a plurality of audio speaker drivers coupled to in a line array to at least one enclosure and each having an input; and
a Bessel circuit having an input for receiving the signal from the amplifier and having a plurality of outputs for coupling to inputs of the audio speaker drivers;
wherein the Bessel circuit includes first means for providing to one of the audio speaker drivers a signal which is in-phase in low frequencies and opposite-phase in high frequencies.

15. The audio speaker system of claim 14 wherein the first means for providing comprises:
an all-pass filter.

16. The audio speaker system of claim 14 wherein:
the Bessel circuit further includes second means for providing to at least one of the audio speaker drivers a signal which is lower strength in low frequencies and higher strength in high frequencies.

17. The audio speaker system of claim 16 wherein the first means for providing comprises:
an all-pass filter.

18. An improved electronic system for driving a Bessel array having a plurality of audio transducers arranged in columns and rows, wherein the improved electronic system has at least one input for receiving at least one signal from at least one amplifier, and wherein the improved electronic system comprises:
a main Bessel circuit including,
a plurality of half-strength, in-phase outputs;
a plurality of full-strength, in-phase outputs;
a plurality of first Bessel circuits including,
a plurality of half-strength, in-phase outputs, and
a plurality of full-strength, in-phase outputs; and
at least one of the main Bessel circuit and the plurality of first Bessel circuits further including at least one of,
an inverting output which provides an in-phase signal in low frequencies and an opposite-phase signal in high frequencies, and
at least one of its plurality of half-strength, in-phase outputs providing a full-strength, in-phase signal in low frequencies and a half-strength, in-phase signal in high frequencies.

19. A Bessel circuit for driving a plurality of audio transducers configured as a Bessel array, the Bessel circuit comprising:
at least one input for receiving at least one input from at least one amplifier;
a plurality of outputs for coupling to drive the plurality of audio transducers;
first circuit paths coupled to the at least one input for providing first signals at a first plurality of the outputs;
second circuit paths coupled to the at least one input for providing second signals at a second plurality of the outputs; and
a third circuit path coupled to the at least one input for providing a third signal at a third one of the outputs;
wherein,
the first signals comprise full-strength, in-phase signals, and one of,
the second signals comprise full-strength, in-phase signals in low frequencies and half-strength, in-phase signals in high frequencies, and
the third signal comprises an in-phase signal in low frequencies and an opposite-phase signal in high frequencies.

20. The Bessel circuit of claim 19 wherein both:
the second signals comprise full-strength, in-phase signals in low frequencies and half-strength, in-phase signals in high frequencies; and
the third signal comprises an in-phase signal in low frequencies and an opposite-phase signal in high frequencies.
